(19) United States
(12) Patent Application Publication
(10) Pub. No.: US 2006/0078680 A1
(43) Pub. Date: Apr. 13, 2006

(54) Method for forming a carbon nanotube and a plasma CVD apparatus for carrying out the method

(76) Inventors: Haruhisa Nakano, Ibaraki-ken (JP); Masaaki Hirakawa, Ibaraki-ken (JP); Hirohiko Murakami, Ibaraki-ken (JP)

Correspondence Address: ARENT FOX PLLC, 1050 CONNECTICUT AVENUE, N.W., SUITE 400, WASHINGTON, DC, 20036, US

(21) Appl. No.: 11/122,232

(22) Filed: May 5, 2005

(30) Foreign Application Priority Data
May 10, 2004 (JP) 139573/2004

(51) Int. Cl. D01F 9/12; C23C 16/26; C23C 16/00

(52) U.S. Cl. 427/249.1; 423/447.3; 118/723 R

(57) ABSTRACT

In forming a carbon nanotube on the surface of a substrate surface by the plasma CVD method in accordance with the prior art, since the substrate is heated by plasma, it is difficult to suitably control the temperature of substrate and thus impossible to form the carbon nanotube at a low temperature. According to the present invention there is provided a method for forming a carbon nanotube comprising steps of introducing a carbon included feedstock gas into a vacuum chamber; generating plasma so that a substrate is not exposed to plasma during a vapor phase growth of the carbon nanotube on a substrate surface; heating the substrate to a predetermined temperature by using a heater; and promoting the growth of the carbon nanotube on the substrate surface with it being contacted by the feedstock gas decomposed by plasma.

### BACKGROUND OF THE INVENTION

1. Field of the Invention

The present invention relates to a method for forming a carbon nanotube and a plasma CVD apparatus for carrying out the method, and more particularly to a method for forming a carbon nanotube and a plasma CVD apparatus for carrying out the method using a plasma CVD method for promoting the vapor phase growth of the carbon nanotube having a vertically aligned orientation relative to a substrate.

2. Description of Background Art

The carbon nanotube has the chemical stability as well as characteristics of emitting electrons in weak electric field and thus is applied for example to an electron source for a FED (Field Emission Display) apparatus.

In case of forming the carbon nanotube, it is preferable that time or labor of refining the carbon nanotube can be saved by directly forming the carbon nanotube on a predetermined portions of a substrate surface, and that length and thickness of each carbon nanotube are substantially uniform and that each carbon nanotube has a vertically aligned orientation relative to the substrate.

It is known in the prior art that the carbon nanotube can be formed for example by using the plasma CVD method. That is, it is possible to use a substrate of transition metal such as Ni, Fe or Co etc., a substrate of alloy including at least one kind of said transition, or a substrate on which surface is formed with any pattern of said metals at any portions of the substrate surface of glass, quartz, Si wafer etc. which is impossible to be formed with any carbon nanotube.

Said substrate is heated for example to a temperature over 500° C. with being exposed to plasma generated after the substrate is disposed within a vacuum chamber kept at a predetermined degree of vacuum and a feedstock gas including hydrocarbon and hydrogen is introduced into the vacuum chamber. Then a desired carbon nanotube is formed on a whole surface or on only patterned surface portions of the substrate by promoting the vapor phase growth of carbon nanotube with the substrate surface being contacted with the feedstock gas decomposed by plasma.

However, since the substrate is heated by energy from plasma generated to decompose the feedstock gas according to the prior art described above, it is impossible to control the temperature of substrate during the promotion of the vapor phase growth of carbon nanotube and thus drop of the temperature of substrate is limited. Accordingly, the carbon nanotube formed on the substrate would be sometimes damaged by high temperature caused by plasma.

### SUMMARY OF THE INVENTION

In view of the above-described of the conventional art, this invention has an object of providing a method for forming a carbon nanotube and a plasma CVD apparatus for carrying out the method in which the temperature of substrate can be controlled during the vapor phase growth of carbon nanotube on the substrate surface and thus the carbon nanotube can be formed at a low substrate temperature without causing any damage on the substrate surface.

According to one aspect of this invention, there is provided a method for forming a carbon nanotube comprising steps of introducing a carbon included feedstock gas into a vacuum chamber; generating plasma so that a substrate is not exposed to plasma during a vapor phase growth of the carbon nanotube on a substrate surface; heating the substrate to a predetermined temperature by using a heating means; and promoting the growth of the carbon nanotube on the substrate surface with it being contacted by the feedstock gas decomposed by plasma.

According to the present invention, plasma is generated after the predetermined substrate has been disposed within the vacuum chamber. In this case the substrate is arranged away from a plasma generating region so as not to be heated without being exposed to plasma energy. The substrate is controllably heated by a separately arranged heating means.

Thus the carbon nanotube is formed on the substrate surface by introducing a carbon included feedstock gas into a vacuum chamber after the substrate has risen to a predetermined temperature and then by promoting the growth of the carbon nanotube on the substrate surface with it being contacted by the feedstock gas decomposed by plasma.

Since the substrate is heated only by the separately arranged heating means, the temperature of the substrate can be easily controlled and thus it becomes possible to promote the vapor phase growth of the carbon nanotube at a low temperature without causing any damage on the substrate surface.

Preferably the heating means is controlled so that the substrate is kept at its predetermined temperature within a range of 300˜700°. At a temperature below 300° C. the growth of carbon nanotube is remarkably reduced, on the contrary at a temperature above 700° C. amorphous carbon is deposited on the substrate surface due to decomposition of hydrocarbon of feedstock at the substrate surface.

It may be possible to form the carbon nanotube on the substrate surface with the substrate being contacted with the feedstock gas decomposed by plasma passing through meshes of a mesh-type shielding means arranged between a plasma generating region and the substrate to prevent the substrate from being exposed to plasma.

Even if the substrate is prevented from being exposed to plasma, it is necessary to impinge the feedstock gas decomposed by plasma with sufficient energy onto the substrate surface so as to form a carbon nanotube having a vertically aligned orientation relative to a substrate. In this case it is preferable to apply a bias voltage to the substrate so as to smoothly feed the feedstock gas toward the substrate.

Said bias voltage applied between the substrate and the mesh-type shielding means is preferably within a range of −400˜200 V. If it is out of a range of −400˜200 V, the substrate “S” and/or carbon nanotube will be damaged, such as due to discharge which would be caused therebetween.

The feedstock gas including carbon may be hydrocarbon or alcohol or either one of them with which at least one of hydrogen, ammonia, nitrogen or argon is mixed

The substrate may have, at least on its surface, a transition metal or an alloy including at least one kind of transition metals.

According to another aspect of this invention, there is provided a plasma CVD apparatus comprising a vacuum chamber within which a substrate stage for laying a substrate thereon and a plasma generating apparatus are arranged, and adapted to promote the vapor phase growth of a carbon nanotube on a surface of the substrate laid on the substrate stage by introducing a carbon included feedstock gas into the vacuum chamber characterized in that the substrate stage is positioned away from a plasma generating region to prevent the substrate from being exposed to plasma generated within the vacuum chamber, and that there is arranged within the vacuum chamber a heating means for heating the substrate to a predetermined temperature.

According to another aspect of this invention, there is provided an another plasma CVD apparatus comprising a vacuum chamber within which a substrate stage for laying a substrate thereon and a plasma generating apparatus are arranged, and adapted to promote the vapor phase growth of a carbon nanotube on a surface of the substrate laid on the substrate stage by introducing a carbon included feedstock gas into the vacuum chamber characterized in that a mesh-type shielding means is arranged between a plasma generating region and the substrate laid on the substrate stage to prevent the substrate from being exposed to plasma generated within the vacuum chamber, and that there is arranged within the vacuum chamber a heating means for heating the substrate to a predetermined temperature.

It is preferable that the distance between the shielding means and the substrate is set at a range within 20˜100 mm. If the distance is shorter than 20 mm the discharge tends to be easily caused and thus the carbon nanotube formed on the substrate “S” or the substrate surface will be damaged due to discharge, on the contrary if the distance is longer than 100 mm the shielding means cannot act as an opposite electrode relative to the substrate although the bias voltage is applied therebetween.

Provision of a bias power source for applying a bias voltage to the substrate enables to impinge the feedstock gas decomposed by plasma with sufficient energy onto the substrate surface so as to form a carbon nanotube having a vertically aligned orientation relative to a substrate.

### EFFECTS OF THE INVENTION

As described above, according to the method for forming a carbon nanotube and the plasma CVD apparatus for carrying out the method of the present invention it is possible to control the temperature of substrate during the carbon nanotube is formed on the substrate surface so as to deposit it at a low temperature without causing any damage on the substrate surface.

### BRIEF DESCRIPTION OF THE DRAWINGS

Additional advantages and features of the present invention will become apparent from the subsequent description and the appended claims, taken in conjunction with the accompanying drawings, wherein:

FIG. 1 is a cross-sectional view schematically showing an arrangement of the plasma CVD apparatus of the present invention;

FIG. 2 is an SEM photograph of a carbon nanotube formed by the method of the present invention; and

FIG. 3 is a TEM photograph of a carbon nanotube formed by the method of the present invention.

### DESCRIPTION OF THE PREFERRED EMBODIMENTS

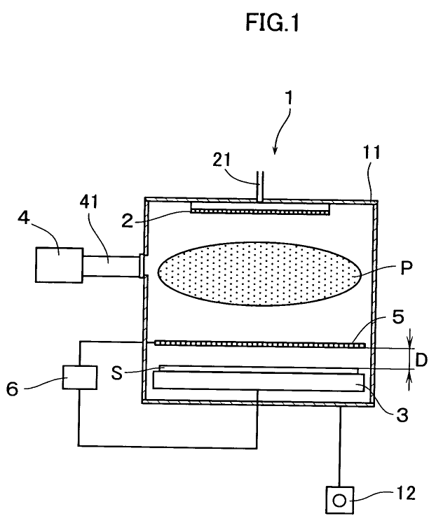

With reference to FIG. 1, a numeral 1 denotes a plasma CVD apparatus. The plasma CVD apparatus 1 has a vacuum chamber 11 provided with an evacuating means 12 such as a rotary pump and a turbo-molecular pump etc. The top of the vacuum chamber 11 is provided with a gas introducing means 2 having a known structure which is connected to a gas source (not shown) via a gas pipe 21.

Hydrocarbon gas such as methane and acetylene etc., or vaporized alcohol, or these gases mixed with at least one of hydrogen, ammonia, nitrogen or argon for improving diluting and catalyzing actions during the vapor phase growth are used as a carbon included feedstock gas introduced into the vacuum chamber 11 for promoting the vapor phase growth of the carbon nanotube on the surface of substrate “S”. Preferably gases such as methane and others not decomposed at a temperature of heated substrate are used.

Within the vacuum chamber 11 there is also arranged a substrate stage 3 for supporting the substrate “S” at a position opposed to the gas introducing means 2. In addition, a microwave generator 4 for generating plasma at a region between the substrate stage 3 and the gas introducing means 2 is connected to the vacuum chamber 11 via a waveguide 41. The microwave generator 4 has a known structure and for example a generator adapted to generate ECR plasma using a slot antenna may be used.

As the substrate “S” which is laid on the substrate stage 3 and on which the carbon nanotube is formed through vapor phase growth, it is possible to use a substrate of transition metal such as Ni, Fe or Co etc., a substrate of alloy including at least one kind of said transition metals, or a substrate on which surface is formed with any pattern of said metals at any portions of the substrate surface of glass, quartz, Si wafer etc. which is impossible to be formed with any carbon nanotube. When depositing any one of said metals on the substrate of glass, quartz, Si wafer, it may be possible to provide, between the substrate and the metal, a layer such as tantalum which does not form any chemical compound.

After the substrate “S” having been laid on the substrate stage 3, the evacuating means 12 is actuated to evacuate the vacuum chamber 11 to a predetermined degree of vacuum and then the microwave generator 4 is actuated to generate plasma. Then after having heated the substrate “S” to a predetermined temperature, the carbon included feedstock gas is introduced into the vacuum chamber 11 to make the substrate “S” be contacted with the feedstock gas decomposed by plasma so as to promote the vapor phase growth of carbon nanotube on the substrate “S”. Thus the carbon nanotube having a vertically aligned orientation relative to the substrate “S” can be formed on the whole surface or only on the patterned portions of the substrate “S”.

Under the circumstances, if the substrate is heated by plasma generated to decompose the feedstock gas as in the conventional way, it is very difficult to control the temperature of substrate during formation of carbon nanotube on a substrate surface and in addition it is impossible to lower the temperature of the substrate. Furthermore it is afraid that the thus formed carbon nanotube would be damaged by direct exposure to plasma.

For solving these problems, according to the present invention the substrate stage 3 is positioned away from a plasma generating region “P”, and a mesh-type shielding means of metal 5 is arranged between a plasma generating region “P” and the substrate “S” opposed to the substrate stage 3 to prevent the substrate “S” from being exposed to plasma generated within the vacuum chamber 11. In addition there is provided within the substrate stage 3 with a heating means e.g. of a resistor heater (not shown) for heating the substrate “S” to a predetermined temperature.

In this case the heating means is controlled so that the substrate “S” is kept at a predetermined temperature within 300˜700° C. during the vapor phase growth of carbon nanotube. At a temperature below 300° C. the growth of carbon nanotube would be remarkably reduced, on the contrary at a temperature above 700° C. amorphous carbon would be deposited on the surface of the substrate “S” due to decomposition of hydrocarbon of feedstock at the substrate surface.

The mesh-type shielding means 5 is made for example of stainless steel and arranged within the vacuum chamber 11 so that it is grounded and adapted to be held in a floating condition. The size of mesh of the shielding means 5 is selected within 1˜3 mm. Accordingly, an ion-sheath region is formed by the shielding means 5 for preventing plasma particles (plasma ion) from entering into a side of the substrate “S”. The effect of preventing exposure of the substrate “S” to plasma is further enhanced by positioning the substrate stage 3 away from the plasma generating region “P”. A mesh size smaller than 1 mm would substantially shut off the gas flow, on the other hand a mesh size larger than 3 mm would substantially reduce the plasma shut off effect.

Even if the substrate “S” is prevented from being exposed to plasma, it is necessary to impinge the feedstock gas decomposed by plasma with sufficient energy onto the substrate surface so as to form a carbon nanotube having a vertically aligned orientation relative to a substrate “S”. Thus a power source 6 for applying a bias voltage to the substrate “S” between the substrate “S” and the shielding means 5 is provided. Thus it is possible to smoothly feed the feedstock gas decomposed by plasma toward the substrate “S” through meshes of the shielding means 5.

The bias voltage is set within a range of −400˜200 V. At a voltage lower than −400 V the carbon nanotube formed on the substrate “S” and/or the substrate surface will be damaged due to discharge, on the contrary at a voltage higher than 200 V the growth velocity of carbon nanotube will be reduced.

A distance “D” between the mesh-type shielding means 5 and the substrate “S” laid on the substrate stage 3 is set at a range within 20˜100 mm. If the distance “D” is shorter than 20 mm the discharge tends to be easily caused and thus the carbon nanotube formed on the substrate “S” or the substrate surface will be damaged due to discharge. If the distance “D” is longer than 100 mm the shielding means 5 cannot act as an opposite electrode relative to the substrate “S” although the bias voltage is applied therebetween, on the contrary the decomposed gases are combined to produce soot and more when the bias voltage does not applied to the substrate

Such an arrangement prevents the substrate “S” from being exposed to plasma when plasma is generated within the vacuum chamber 11. That is, the substrate “S” is not heated by energy from plasma and heated by the heating means arranged within the substrate stage 3. Accordingly it becomes possible to easily control the temperature of the substrate “S” and to form the carbon nanotube on the surface of the substrate “S” at a low temperature and thus without causing any damage thereon.

Although it is described that the heating means is arranged within the substrate stage 3 in the illustrated embodiment, the present invention is not limited to the illustrated embodiment. Any heating means may be used if it can heat the substrate “S” to a predetermined temperature.

Although it is described that the bias voltage applies to the substrate “S” between the substrate “S” and the mesh-type shielding means 5 as to impinge the feedstock gas decomposed by plasma with sufficient energy onto the substrate surface in the illustrated embodiment, the present invention is not limited to the illustrated embodiment. Even if the bias voltage does not apply to the substrate “S” therebetween, the carbon nanotube can be formed without causing any damage on the substrate surface. Further, when a insulator layer, such as SiO₂ is formed on the substrate, the bias voltage, which can be set within a range of 0˜200 V, may apply to the substrate to prevent from charging effect at the insulator layer. In this case, at a voltage higher than 200 V the growth velocity of carbon nanotube will be reduced.

### Exemplary Embodiment 1

A carbon nanotube was formed on a predetermined substrate “S” by promoting its vapor phase growth using the plasma CVD apparatus 1 shown in FIG. 1. The distance “D” between the substrate “S” and the shielding means 5 was set at 20 mm. The substrate “S” was a silicon substrate coated with a tantalum film having a thickness of 100 nm deposited by sputtering method and then coated with a Fe film having thickness of 5 nm on the tantalum film by a EB vapor deposition method.

The substrate “S” thus formed was laid on the substrate stage 3 and substrate cleaning was carried out as its pretreatment after evacuation of the vacuum chamber 11 by actuating the evacuating means 12 until it became a pressure less than 3×10⁻¹ Pa.

Hydrogen was introduced into the vacuum chamber 11 at a flow rate of 80 sccm via the gas introducing means 2 and was kept at a pressure of 2.67×10² Pa. Then plasma was generated with actuation of the microwave generator 4 after heating the substrate “S” to 500° C. with actuation of the heating means. Then the substrate “S” was cleaned by applying the bias voltage to the substrate “S” with actuation of the bias power source 6 so that the voltage of the substrate “S” was −150 V relative to the shielding means 5. The actuation of the bias power source 6 was stopped after laps of 10 minutes and the introduction of gas was stopped after stop of actuation of the microwave generator 4. Then the vacuum chamber 11 was evacuated again until the pressure within the vacuum chamber 11 was reduced below 3×10⁻¹ Pa.

Then methane and hydrogen are introduced into the vacuum chamber 11 at flow rates of 20 sccm and 80 sccm respectively to use gas mixture of methane and hydrogen as the carbon included feedstock gas. The operation of the evacuating means 12 was controlled so that the pressure within the vacuum chamber 11 was kept at 2.67×10² Pa. Then plasma was generated with actuating the microwave generator 4 after the substrate “S” was heated to 500° C. with actuation of the heating means. Thus the carbon nanotube was formed on the substrate “S” with applying the bias voltage to the substrate “S” by the bias power source 6 so that the voltage of the substrate “S” was −300 V relative to the shielding means 5.

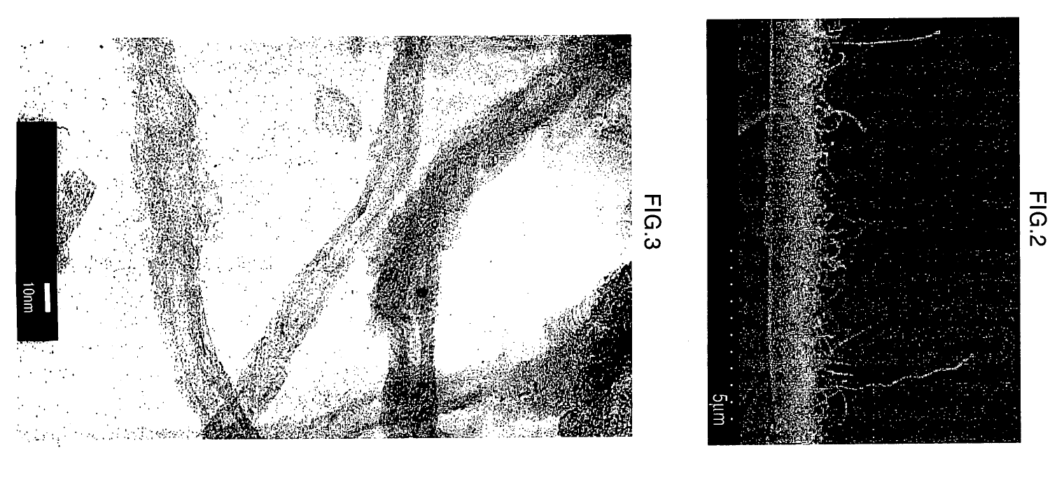

FIG. 2 is an SEM photograph of a carbon nanotube formed by the vapor phase growth on a substrate “S” for 60 minutes in accordance with the process described above and FIG. 3 is its TEM photograph. According to these photographs it can be seen that the carbon nanotubes are formed as having a length mainly of 4 μm and partially 10 μm vertically to the substrate “S”. This tube has hollow portions and thus is confirmed that these are carbon nanotubes.

### Exemplary Embodiment 2

Exemplary Embodiment 2 is different from the above Exemplary Embodiment 1 at a point that the substrate “S” was a silicon substrate coated with a tantalum film having a thickness of 100 nm deposited by sputtering method and then coated with a Fe film having thickness of 5 nm on the tantalum film by a EB vapor deposition method and then coated with a SiO₂ film so as to be exposed to a part of Fe film by sputtering method. Also Exemplary Embodiment 2 is different from the above Exemplary Embodiment 1 at a point that the substrate “S” was cleaned by applying the bias voltage to the substrate “S” with actuation of the bias power source 6 so that the voltage of the substrate “S” was −300 V relative to the shielding means 5 and then the actuation of the bias power source 6 was stopped after laps of 5 minutes. Further, the carbon nanotube was formed on the substrate “S” without applying the bias voltage to the substrate “S”.

According to above Exemplary Embodiment 2, it is confirmed that the carbon nanotubes, which heights are aligned, were formed on Fe film acting as a catalyst.

The present invention has been described with reference to the preferred embodiment. Obviously, modifications and alternations will occur to those of ordinary skill in the art upon reading and understanding the preceding detailed description. It is intended that the present invention be construed as including all such alternations and modifications insofar as they come within the scope of the appended claims or the equivalents thereof.

1. A method for forming a carbon nanotube comprising steps of introducing a carbon included feedstock gas into a vacuum chamber; generating plasma so that a substrate is not exposed to plasma during a vapor phase growth of the carbon nanotube on a substrate surface; heating the substrate to a predetermined temperature by using a heating means; and promoting the growth of the carbon nanotube on the substrate surface with it being contacted by the feedstock gas decomposed by plasma.

2. A method for forming a carbon nanotube of claim 1 wherein the heating means is controlled so that the substrate is kept at its predetermined temperature within a range of 300˜700° C.

3. A method for forming a carbon nanotube of claim 1 wherein the growth of the carbon nanotube on the substrate surface is promoted by contacting the feedstock gas decomposed by plasma passed through meshes of a mesh-type shielding means arranged between a region wherein plasma is generated and the substrate.

4. A method for forming a carbon nanotube of claim 1 wherein a bias voltage is applied to the substrate.

5. A method for forming a carbon nanotube of claim 4 wherein the bias voltage applied between the substrate and the mesh-type shielding means is set within a range of −400˜200 V.

6. A method for forming a carbon nanotube of claim 1 wherein the feedstock gas including carbon is hydrocarbon or alcohol or either one of them with which at least one of hydrogen, ammonia, nitrogen or argon is mixed.

7. A method for forming a carbon nanotube of claim 1 wherein the substrate has, at least on its surface, a transition metal or an alloy including at least one kind of transition metals.

8. A plasma CVD apparatus comprising a vacuum chamber within which a substrate stage for laying a substrate thereon and a plasma generating apparatus are arranged, and adapted to promote the vapor phase growth of a carbon nanotube on a surface of the substrate laid on the substrate stage by introducing a carbon included feedstock gas into the vacuum chamber characterized in that the substrate stage is positioned away from a plasma generating region to prevent the substrate from being exposed to plasma generated within the vacuum chamber, and that there is arranged within the vacuum chamber a heating means for heating the substrate to a predetermined temperature.

9. A plasma CVD apparatus comprising a vacuum chamber within which a substrate stage for laying a substrate thereon and a plasma generating apparatus are arranged, and adapted to promote the vapor phase growth of a carbon nanotube on a surface of the substrate laid on the substrate stage by introducing a carbon included feedstock gas into the vacuum chamber characterized in that a mesh-type shielding means is arranged between a plasma generating region and the substrate laid on the substrate stage to prevent the substrate from being exposed to plasma generated within the vacuum chamber, and that there is arranged within the vacuum chamber a heating means for heating the substrate to a predetermined temperature.

10. A plasma CVD apparatus of claim 9 wherein the distance between the shielding means and the substrate is set at a range within 20˜100 mm.

11. A plasma CVD apparatus of claim 8 wherein there is provided a bias power source for applying a bias voltage to the substrate.

12. A plasma CVD apparatus of claim 9 wherein there is provided a bias power source for applying a bias voltage to the substrate.

13. A plasma CVD apparatus of claim 10 wherein there is provided a bias power source for applying a bias voltage to the substrate.

14. A method for forming a carbon nanotube of claim 2 wherein the growth of the carbon nanotube on the substrate surface is promoted by contacting the feedstock gas decomposed by plasma passed through meshes of a mesh-type shielding means arranged between a region wherein plasma is generated and the substrate.

15. A method for forming a carbon nanotube of claim 14 wherein a bias voltage is applied to the substrate.

16. A method for forming a carbon nanotube of claim 15 wherein the bias voltage applied between the substrate and the mesh-type shielding means is set within a range of −400˜200 V.

17. A method for forming a carbon nanotube of claim 2 wherein a bias voltage is applied to the substrate.

18. A method for forming a carbon nanotube of claim 17 wherein the bias voltage applied between the substrate and the mesh-type shielding means is set within a range of −400˜200 V.

19. A method for forming a carbon nanotube of claim 3 wherein a bias voltage is applied to the substrate.

20. A method for forming a carbon nanotube of claim 19 wherein the bias voltage applied between the substrate and the mesh-type shielding means is set within a range of −400˜200 V.
